(19) United States
(12) Patent Application Publication
(10) Pub. No.: US 2014/0028307 A1
(43) Pub. Date: Jan. 30, 2014

(54) MAGNETORESISTIVE SENSOR SYSTEMS AND METHODS HAVING A YAW ANGLE BETWEEN PREMAGNETIZATION AND MAGNETIC FIELD DIRECTIONS

(71) Applicant: Udo Ausserlechner, Villach (AT)

(72) Inventor: Udo Ausserlechner, Villach (AT)

(21) Appl. No.: 13/559,206

(22) Filed: Jul. 26, 2012

(51) Int. Cl. G01R 33/02; G01R 33/09

(52) U.S. Cl. 324/252; 324/244

(57) ABSTRACT

Embodiments relate to magnetoresistive (xMR) sensors which provide a yaw angle between a reference premagnetization direction of the sensor layer and the magnetic field to be detected, or between a direction of a bias magnetic field and the magnetic field to be detected. In an embodiment, an xMR sensor is rotated or tilted with respect to a direction of a magnetic field to be sensed such that a premagnetization direction of the reference premagnetization layer of the xMR sensor is also rotated or tilted at some yaw angle with respect to the direction of the magnetic field. In another embodiment, a bias magnet or other source is used with sensors not having premagnetization or reference layers, such as anisotropic magnetoresistive (AMR) sensors, and the direction of the bias magnetic field is also tilted or rotated with respect to the direction of the magnetic field to be detected.

### TECHNICAL FIELD

The invention relates generally to magnetoresistive sensors and more particularly to introducing a yaw angle between a premagnetization direction of the magnetoresistive sensor and direction of a magnetic field to be detected.

### BACKGROUND

Differential magnetic field sensors detect a difference in a magnetic field at two different positions. One particular type of differential magnetic field sensor is a magnetoresistive (xMR) sensor, which can include a giant magnetoresistive (GMR) sensor, colossal magnetoresistive (CMR) sensor, tunneling magnetoresistive (TMR) sensor or anisotropic magnetoresistive (AMR) sensor. GMRs, TMRs and CMRs each comprise a pinned layer that is premagnetized with a particular reference direction during manufacturing. Each element therefore has its own reference magnetization direction no matter where it is positioned. Typically, each element in a differential sensor will have the same reference magnetization direction because this makes manufacturing more efficient, though it is also possible for different xMR elements of the same sensor to have different directions of magnetization. In contrast, AMRs require a bias magnet to create the same magnetic field on both sensor elements in a differential sensor system.

One particular type of differential magnetic field sensor is a wheel-speed sensor, in which a magnetic field is generated by a target, such as a pole wheel or a tooth wheel. Each target has a period, lambda, related to the length of adjacent north-south poles or a tooth-notch. The target moves in a particular direction, such as the x-direction, and generates a vector magnetic field (Bx, By, Bz) with a sinusoidal dependence on the direction of rotation. The differential magnetic field sensor is positioned some distance away from the target, defining an air gap between the surface of the target and the sensor elements. The amplitudes of the magnetic field components decrease exponentially as the air gap increases.

For small air gaps and large lambda, the amplitude of the magnetic field becomes very large, which can drive the xMR sensor elements into saturation. This can create an output signal like that shown in FIG. 1, which has shoulders or flat areas near the zero-crossings. This saturation and resulting output signal are undesirable. Moreover, this problem affects not only differential xMR sensors but also monocells and gradiometers of a higher order than differential sensors, which can be similarly affected by large currents.

One solution, of course, could be to use an xMR sensor which has a larger saturation field in order to avoid saturation of the sensor. These sensors, however, typically have lower sensitivity, while some technologies, such as GMR, would require a reduction in GMR strip width which has obvious physical and manufacturing limitations. Another solution is to use monocells, such as AMRs, but they are typically not as robust against background disturbances. Linear sensors, such as Hall sensors, could be used, but they do not provide as much magnetic sensitivity, leading to noise, jitter and a smaller airgap.

Therefore, there is a need for improved xMR sensors.

### SUMMARY

Embodiments relate to magnetoresistive sensors having improved non-saturation ranges.

In an embodiment, a sensor comprises at least one magnetic field sensor element having a reference magnetization direction, wherein the at least one magnetic field sensor element is arranged such that a predetermined angle greater than about 0 degrees and less than about 90 degrees exists between the reference magnetization direction and a direction of a magnetic field to be sensed by the sensor.

In an embodiment, a sensor comprises a bias magnetic field source configured to induce a bias magnetic field; and at least one magnetic field sensor element, wherein the at least one magnetic field sensor element is arranged such that a predetermined angle greater than about 0 degrees and less than about 90 degrees exists between a direction of magnetization of the at least one magnetic field sensor element related to the bias magnetic field and a direction of a magnetic field to be sensed by the sensor.

In an embodiment, a method of extending a non-saturation range of a magnetoresistive magnetic field sensor comprises determining a direction of a magnetic field to be sensed; and arranging a magnetoresistive magnetic field sensor to form a predetermined non-zero angle between a magnetization direction of the magnetoresistive magnetic field sensor and the direction of the magnetic field to be sensed.

### BRIEF DESCRIPTION OF THE DRAWINGS

The invention may be more completely understood in consideration of the following detailed description of various embodiments of the invention in connection with the accompanying drawings, in which:

FIG. 1 is a graph of an output signal.

FIG. 2 is a diagram of a sensor system according to an embodiment.

FIG. 3A is a diagram of a magnetoresistive strip according to an embodiment.

FIG. 3B is a diagram of a magnetoresistive strip according to an embodiment.

FIG. 3C is a diagram of a magnetoresistive strip according to an embodiment.

FIG. 4 is a graph of magnetoresistive element resistance versus magnetic field strength according to an embodiment.

FIG. 5A is a diagram of a sensor system according to an embodiment.

FIG. 5B is a resistor bridge diagram of the resistors of FIG. 5A.

FIG. 5C is a diagram of a sensor system according to an embodiment.

FIG. 6 is a graph of magnetoresistive bridge output signal versus rotation angle according to an embodiment.

FIG. 7 is a diagram of a sensor system according to an embodiment.

FIG. 8A is a diagram of a current sensor according to an embodiment.

FIG. 8B is a diagram of a current sensor according to an embodiment.

FIG. 9 is a diagram of a magnetoresistive strip according to an embodiment.

FIG. 10 is a diagram of a current sensor according to an embodiment.

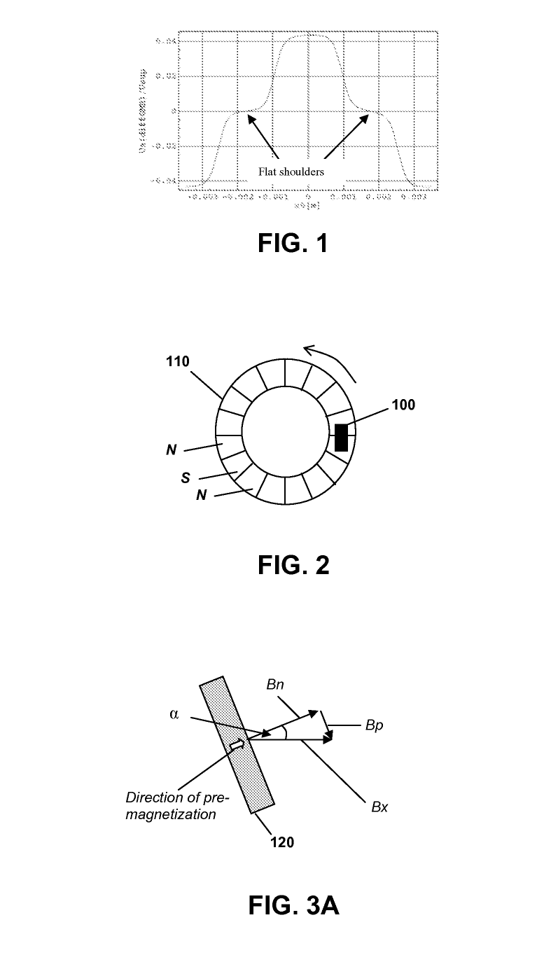

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

Embodiments relate to magnetoresistive (xMR) sensors which provide a yaw angle between a reference premagnetization direction of the sensor layer and the magnetic field to be detected, or between a direction of a bias magnetic field and the magnetic field to be detected. In an embodiment, an xMR sensor is rotated or tilted with respect to a direction of a magnetic field to be sensed such that a premagnetization direction of the reference premagnetization layer of the xMR sensor is also rotated or tilted at some yaw angle with respect to the direction of the magnetic field. In another embodiment, a bias magnet or other source is used with sensors not having premagnetization of reference layers, such as anisotropic magnetoresistive (AMR) sensors, and the direction of the bias magnetic field is also tilted or rotated with respect to the direction of the magnetic field to be detected. In embodiments, this can increase the dynamic range of the xMR sensor, preventing the sensor from saturating and providing advantages with respect to conventional approaches.

Referring to FIG. 2, a sensor 100 and target 110 are depicted. Target 110 is a magnetic pole wheel in the embodiment of FIG. 2 with alternating north, south, north, etc., segments, but can comprise a tooth wheel or some other suitable target in embodiments. Sensor 100 can comprise a monocell, differential or gradiometric sensor in embodiments, further comprising an xMR sensor, a Hall effect sensor or some other suitable magnetic field sensor. Sensor 100 is spaced apart from target 110 by a distance referred to as the air gap, which is generally into or out of the page as illustrated in FIG. 2 but can vary in other depictions and embodiments.

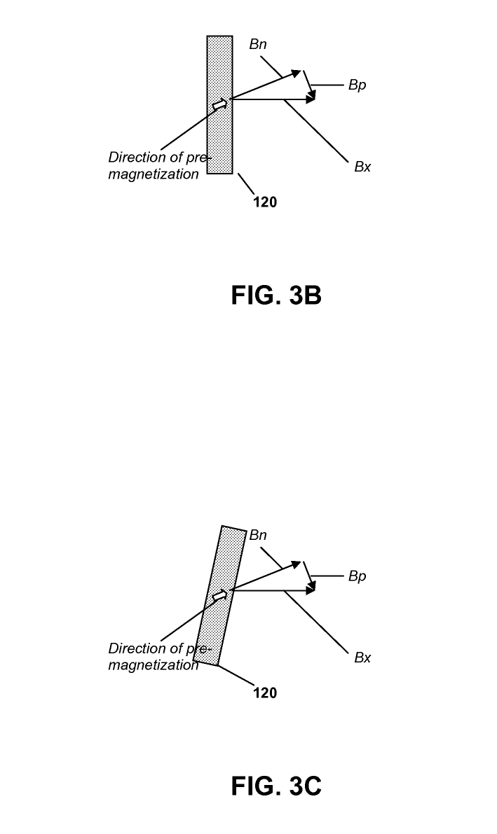

Sensor 100 comprises a GMR sensor in an embodiment, a GMR strip 120 of which is depicted in FIG. 3. While particular examples may be used herein to illustrate and discuss various aspects of embodiments, these examples are in no way to be considered limiting with respect to other embodiments. For example, one skilled in the art can appreciate the applicability of aspects of a GMR embodiment to other xMR sensors, such as TMR or CMR. AMR and other sensor types requiring a bias magnet and/or not having a pinned layer premagnetized with a reference magnetic field direction will be discussed herein below.

In the GMR embodiment depicted in FIG. 3A, sensor 100 comprises a GMR strip 120 which is premagnetized with a reference magnetic field in the direction indicated by the arrow on strip 120. In FIG. 3A, the premagnetization direction is perpendicular to a length, or longer dimension, of GMR strip 120. In other words, it does not align the shape anisotropy effect “easy axis” of GMR strip 120. The shape anisotropy effect is the result of the demagnetization field that is established at the edges of magnetic structures. As a result of specific shapes, such as narrow strips, there are preferred axes of magnetization, for example, along the length of each strip. This is what is referred to as the “easy axis.” For GMR strip 120, the easy axis would be parallel with the length dimension of GMR strip 120, but instead here it is perpendicular thereto. This direction can vary in other embodiments, but in general herein embodiments comprise elements for which the easy axis and the premagnetization direction (or the bias magnetic field direction, in the case of AMR elements, for example) do not align.

Moreover, a yaw angle is also introduced in embodiments, where the yaw angle is between the premagnetization (or bias field) direction and the magnetic field to be detected. In FIG. 3A, the field to be measured is Bx, though again this can vary in embodiments and is used herein as an example only. In FIG. 3A, GMR strip 120 is tilted or rotated with respect to Bx such that the direction of the premagnetization is at a yaw angle α. The Bx-field then can be decomposed into a portion Bn that is parallel to the direction of premagnetization of strip 120 and Bp, which is perpendicular thereto.

The orientation of GMR strip 120 need not be changed in other embodiments, however. Referring to FIG. 3B, GMR strip 120 has premagnetization direction is not perpendicular to the length of strip 120 but rather is at an angle thereto. In FIG. 3C, the field is not perpendicular to the length while strip 120 is also tilted or rotated with respect to the direction of the field to be measured, Bx. Instead, the consideration is the relative orientation of the premagnetization direction of the pinned layer of GMR strip 120 with the direction of the magnetic field Bx to be sensed. Thus, FIGS. 3A-3C are only three examples of myriad possibilities of other embodiments.

In general, the orientation of GMR 120 is arbitrary in embodiments because the orientation of GMR strip 120 defines the shape anisotropy, whereas the direction of premagnetization of strip 120 defines the magnetic anisotropy. In embodiments like FIG. 3A in which the direction of premagnetization is perpendicular to the length dimension of strip 120, both shape and magnetic anisotropies favor the same direction. In embodiments like FIGS. 3B and 3C, however, the effects of the two anisotropies can offset or compete with one another. This competition can be used advantageously in embodiments, such as in differential sensors in which it can be desired to reduce manufacturing costs by magnetizing all elements on a substrate in the same direction but provide different axes in different individual elements.

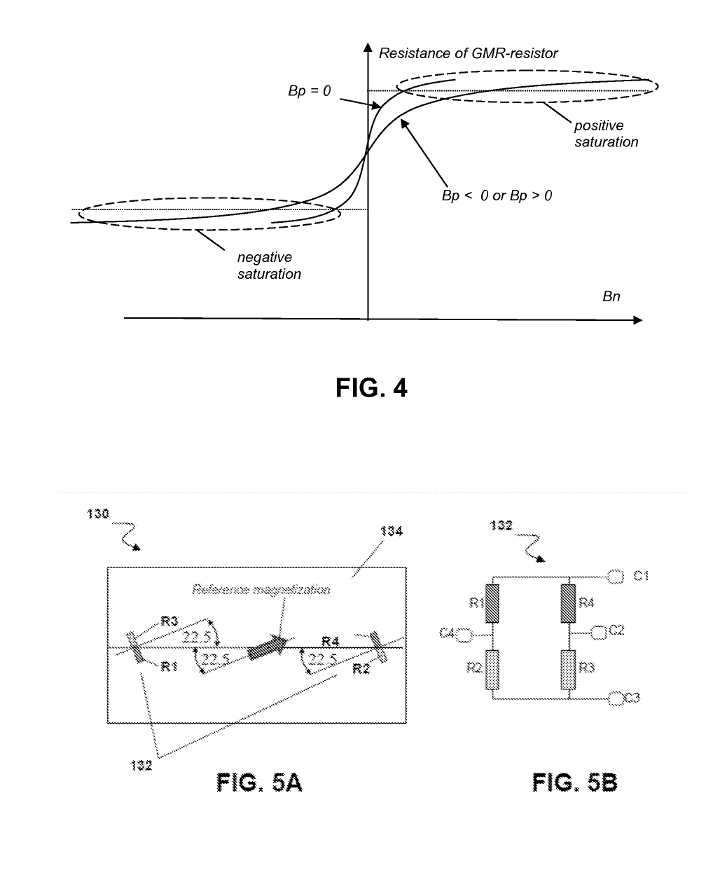

In general, the larger the magnitude of Bp, the smaller the magnetic sensitivity of GMR strip 120 to Bn. In FIG. 4, the resistance of GMR strip 120 is plotted against Bn. For Bp=0, the slope of the signal is much steeper than that for Bp<0 or Bp>0, meaning the sensitivity of GMR strip 120 is higher when Bp=0. This effect, while seemingly negative, actually can be used to increase the dynamic range of GMR strip 120. If the magnetic field to be sensed is small, then Bp is also small and should have no significant impact on the magnetic sensitivity of GMR strip 120. Moreover, GMR strip 120 has a maximum magnetic sensitivity at large air gaps when the magnetic field is also small, leading to a similar results: minimal effect of Bp. This changes, of course, at smaller air gaps, but with smaller air gaps the strength of the magnetic field increases such that decreased magnetic sensitivity is of lesser concern. As can be seen in FIG. 4, at Bp<0 and Bp>0 (i.e., |Bp|), Bn can become higher before saturation is reached.

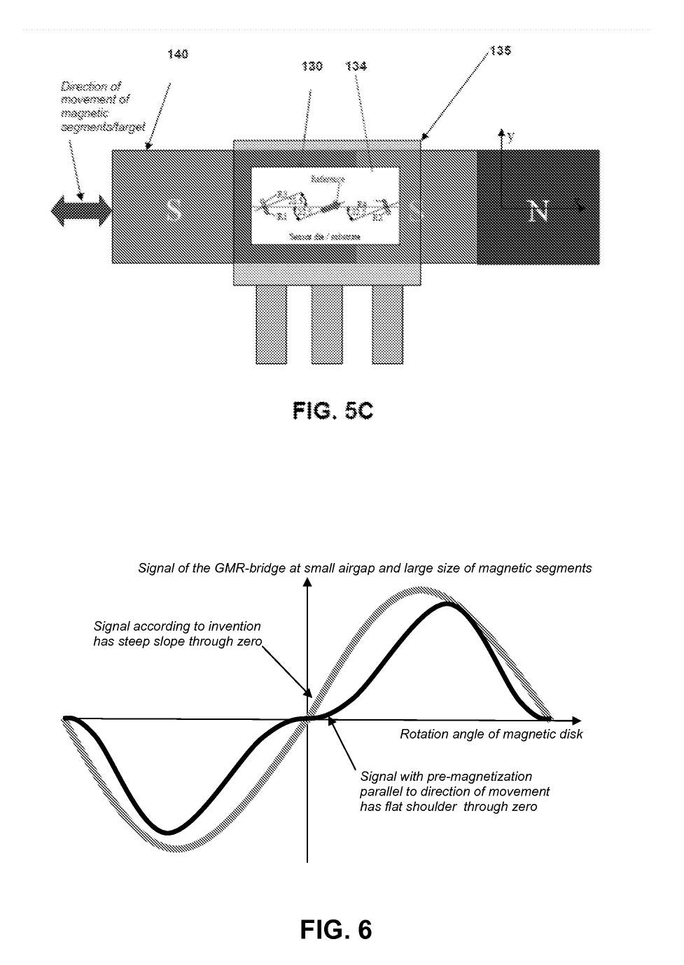

With this context, an embodiment of a wheel-speed sensor 130 will now be discussed with reference to FIG. 5. Wheel-speed sensor 130 comprises an xMR sensor bridge 132 arranged on a die or substrate 134 and within a package or mold body 135. In one embodiment, xMR sensor bridge comprises a plurality of GMR resistors R1, R2, R3 and R4. As previously mentioned, while examples will be discussed herein using particular technologies, e.g., GMR, other technologies, e.g., TMR or CMR, can be substituted in other embodiments. Moreover, other suitable sensor types, including monocells and gradiometers, also can be used in embodiments. Monocells, for example, sample the magnetic field at a single location, whereas gradiometers sample the field at multiple locations and then subtract the results to provide spatial derivatives of the field. Therefore, the use of a GMR sensor bridge in this embodiment of a wheel-speed sensor is but one example used for illustrative purposes.

FIG. 5B is a circuit diagram of a bridge 132 coupling arrangement of sensor elements R1-R4. In this embodiment, the four sensor elements R1-R4 form a full bridge, though other configurations and arrangements can be used in other embodiments. GMR resistors R1-R4 each have the same reference magnetization direction of their respective pinned layers in the embodiment of FIG. 5, illustrated by the reference magnetization directional arrow in FIG. 5A. As in the embodiment of FIG. 3A, the reference magnetization direction of resistors R1-R4 is perpendicular with the length of each of the resistors R1-R4, and the reference magnetization direction is the same for each resistor R1-R4. Thus, sensor 130 can be magnetized in a single step during manufacturing.

In the embodiment of FIG. 5A, the reference magnetization direction is at an angle of about 22.5 degrees with respect to an axis running horizontally on the page, e.g., parallel with a longer side of substrate 134 as depicted. In other words, the reference magnetization direction is at an angle of about 22.5 degrees with respect to the direction of the magnetic field to be detected. In embodiments comprising pole or target wheels, the direction of the magnetic field to be detected corresponds to the direction of rotation or movement of the wheel. The particular angle can vary in embodiments, with 22.5 degrees being one example. In embodiments, this angle is a non-zero angle that is greater than about 0 degrees and less than about 90 degrees, such as between about 5 degrees and about 50 degrees, or between about 15 degrees and about 30 degrees, or about 22.5 degrees in one embodiment. Referring also to FIG. 5C, this 22.5-degree angle, the yaw angle, will be present between the reference magnetization direction and the component of the magnetic field projected by the target 140 into the surface of substrate 134, i.e., aligned with the direction of movement of target wheel 140 when the center of substrate 134 is above the center of target wheel 140. In one embodiment, the direction of movement is the +/−x-direction, and the center of substrate 134 being above the center of target wheel 140 is defined as being at y=0, as shown in FIG. 5C.

The position of substrate 134 at y=0 with respect to target 140 can be considered an ideal position in one embodiment, but it need not be so in all embodiments. At this position, a large Bx-field generally is present while at the same time the By-field vanishes. Moving substrate slightly in a +/−y-direction creates a By-field component that is generally undesired. The Bz-field component is irrelevant for xMR sensors and therefore will not be discussed in detail.

The output of sensor 130 is shown in FIG. 6 for two situations: the black line for a yaw angle=0, and the lighter line for a yaw angle of 22.5 degrees as depicted in FIG. 5. With a 0-degree yaw angle, the undesirable signal output form can be seen, with flat portions or shoulders at the O-crossing where the sensor saturates because of a small air gap and large Bx-field component.

An improved signal output is seen for the yaw angle of 22.5 degrees as in FIG. 5, which is steeper through the O-crossing with no flat or shoulder portions. A steep signal slope at the zero crossing is desirable in embodiments because it indicates sensor 130 is generating pulses with slopes at the zero crossing. Here the Bx-field component can be broken out into Bn and Bp (see FIG. 3) for the embodiment of FIG. 5 having an angle of 22.5 degrees:

Bn=Bx*cos(22.5)=0.92*Bx

Bp=Bx*sin(22.5)=0.38*Bx

Because Bp scales linearly with Bn, Bp increases the saturation field of GMR resistors R1-R4 very efficiently. Thus, not all of the resistors R1-R4 are deep in the same saturation, positive or negative, because the absolute value of Bp is greater than 0 which helps to avoid the flat shoulders in the signal and increase the zero-crossing slope.

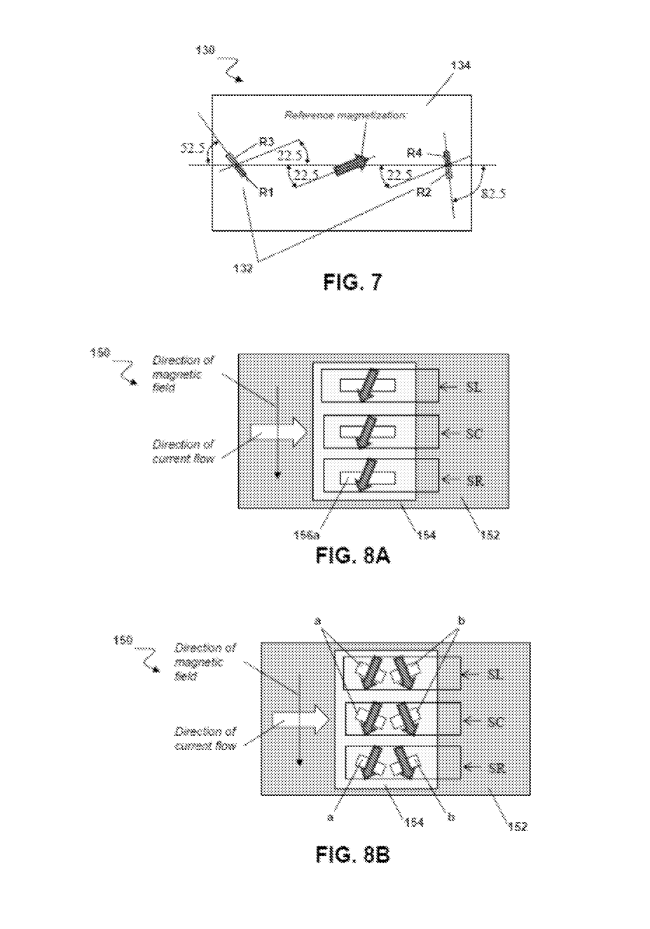

In the embodiment of FIG. 5, resistors R1-R4 all have the same reference magnetization direction and are positioned at the same angle with respect thereto. Referring to FIG. 7, all of resistors R1-R4 need not be positioned at the same angle. In FIG. 7, resistors R1 and R3 are positioned at 52.5 degrees, while resistors R2 and R4 are positioned at 82.5 degrees. In other embodiments, resistors R2 and R3 can be twisted one way (e.g., clockwise) while resistors R1 and R4 are twisted another (e.g., counterclockwise). Additionally, the angles need not be the same. For example, resistors R1 and R3 can be rotated clockwise by a first angle, while resistors R2 and R4 can be rotated counter-clockwise by a second angle different from the first.

Another example embodiment relates to a current sensor, in which the magnetic field induced by current flowing in a conductor, such as a wire or bus bar, is sensed. Referring to FIG. 8, two example embodiments are depicted. In each, the direction of current flow is denoted by the large arrow on the left, while the magnetic field direction is shown by the smaller arrow on the left.

In FIG. 8A, a sensor 150 is positioned proximate a conductor 152, such as a bus bar or a current rail, and comprises three sensor elements SL, SC and SR arranged on a die or substrate 154. In one embodiment, sensor elements SL, SC and SR comprise GMR strips. In other embodiments, the sensor elements SL, SC and SR comprise AMR, TMR or some other suitable technology.

The direction of the magnetic field to be sensed is perpendicular to both the direction of current flow and the longer length dimension of the sensor elements SL, SC and SR. As depicted, the yaw angle between the direction of current flow and the reference magnetization direction is about 22.5 degrees, but as discussed elsewhere herein can vary in other embodiments.

Sensor 150 is a differential sensor, such that the output relates to the difference in magnetic fields sensed by sensor elements, i.e., SL-SC and SR-SC. The introduction of the yaw angle has a self-stabilizing effect on sensor 150, as in other embodiments, by extending the range of sensor elements SC, SL and SR before saturation occurs.

In the embodiment of FIG. 8B, each sensor element SL, SC, SR comprises two sensor portions a and b coupled with one another in series or in parallel. Again, sensor elements can comprise GMR or some other technology, such as AMR or TMR, in embodiments. The sensor element portions, e.g., SLa and SLb, are each themselves tilted or twisted on substrate 154, and each introduces a yaw angle between the reference premagnetization direction and the direction of the magnetic field to be detected. Here each angle is about 22.5 degrees but in opposing directions, and the reference magnetization direction of each sensor portion a, b is indicated by the arrow on that particular portion. As in FIG. 8A, the yaw angle provides a range extension for each sensor element and therefore an improved output signal.

As previously mentioned, embodiments can comprise AMR elements. These embodiments include but are not limited to current sensors. AMR elements, as previously mentioned, do not have a pre-magnetization direction defined during manufacturing but instead rely on a bias magnet to create a bias magnetic field. Thus, AMR embodiments can comprise a bias magnet or some other suitable structure to provide a bias magnetic field. For example, in an embodiment a wire or plurality of wires or some other suitable conductive structure is provided proximate the AMR element, such that a magnetic field can be induced in operation by injecting a sufficiently large current into the wire or wires to induce a sufficiently large bias magnetic field to form a single magnetic state in the soft layer of the AMR element. The soft magnetic layer of the AMR element can develop multiple different magnetization directions due to, e.g., hysteresis or mechanical shock, such that a biasing field induced by a bias magnet or other structure is needed to ensure a single magnetic domain of the soft magnetic layer of the AMR element. Absent a single magnetic domain, the AMR element can be less accurate, which is clearly undesired.

Regardless of the methodology, the bias magnetic field is aligned in embodiments with the easy axis of the AMR element, which is defined by the shape anisotropy of the AMR element. The shape anisotropy effect, as previously mentioned in the context of GMR elements, is the result of the demagnetization field that is established at the edges of magnetic structures. As a result of specific shapes, such as narrow strips, there are preferred, or easy, axes of magnetization, for example, along the length of each strip. For AMR elements, then, the easy axis, and therefore also the bias magnetic field, generally is in the direction of the length or longer dimension of an AMR strip.

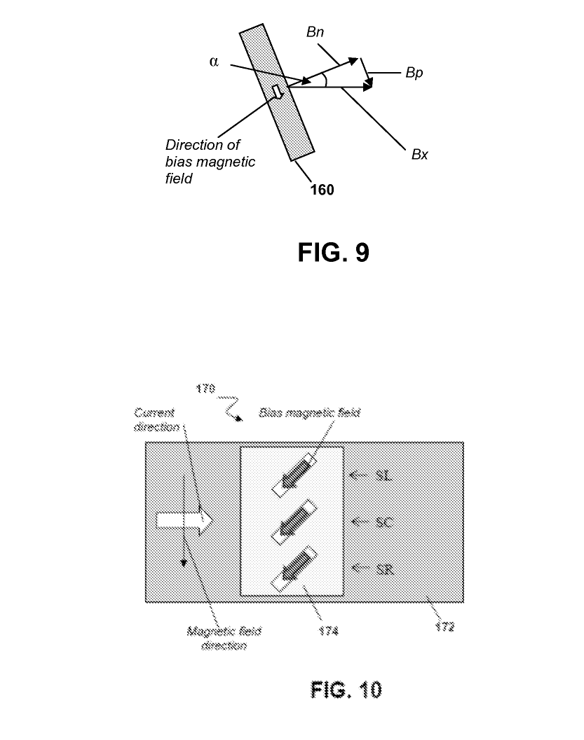

Referring to FIG. 9, an AMR strip 160 is depicted. The direction of the bias magnetic field applied to strip 160 is as indicated, being parallel with the length, or longer, dimension of strip 160 as depicted. As previously discussed, the bias magnetic field can be a constant field induced by a bias magnet, a pulsed field induced by a wire or other conductive structure, or some other suitable field. In the case of a pulsed field, currents of either polarity can be used, such that the sign of the bias magnetic field changes but not the direction.

The field to be detected, referred to as Bx, can be decomposed into Bp and Bn, where Bp is parallel to the bias magnetic field and Bn is orthogonal to the bias magnetic field. The yaw angle is then a, the tangent of which is Bp/Bn. In operation, both Bn and Bp increase as Bx increases, with Bp adding to the bias magnetic field because they are parallel. The magnetic sensitivity of AMR strip 160 is its change in resistance over the applied field Bx, and the sensitivity decreases with larger bias magnetic fields. This means that Bp has the same effect, increasing with larger fields to be measured and thereby reducing the magnetic sensitivity of AMR strip 140, which increases the linear field range and range of magnetic fields to be measured at which saturation occurs. Refer also to FIG. 4.

Similar to the GMR embodiment of FIG. 8, AMR strip 160 also can be used in a current sensor. Referring to FIG. 10, an AMR current sensor 170 is depicted. Sensor 170 is positioned proximate a current conductor 172, such as a current rail, bus bar or other suitable structure through which current flows, to be measured by sensor 170. The direction of current flow is indicated in FIG. 10, as is the direction of the magnetic field induced by the current flow.

Sensor 170 is a second-order differential sensor in this embodiment, comprising three AMR strips SL, SC and SR arranged on a die or substrate 174. The output of sensor 170 is related to the difference between the fields detected at SL and SC, and the difference between the fields detected at SR and SC. In other embodiments, the number and arrangement of AMR strips can vary. Each AMR strip SL, SC and SR is arranged to provide a yaw angle between the direction of the magnetic field to be measured and the direction of the bias magnetic field of about 45 degrees in the depicted embodiment, though as discussed in the context of other examples and embodiments this angle can vary.

Given the yaw angle, the effective bias magnetic field depends on the applied bias magnetic field and a portion of the magnetic field generated by the current flow. At large positive currents in conductor 172, these two portions are added and the effective bias magnetic field is increased, which has the positive effect of linearizing AMR sensor 170. If the direction of current flow is reversed, however, the portion related to the current flow is subtracted from the applied bias magnetic field, and linearity is reduced. Thus, to improve linearity at negative currents, the direction of the bias magnetic field should be reversed.

Embodiments thereby provide sensors, such as monocell or differential magnetic field sensors, arranged such that a yaw angle is provided between the reference magnetization or bias magnetic field direction and the direction of the magnetic field to be detected. The angle can have the effect of stabilizing the sensor by extending its range, preventing sensor elements from going into saturation at lower magnetic fields. Embodiments have applicability to a variety of sensors, including magnetoresistive, such as GMR, AMR and others.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A sensor comprising:
at least magnetic field sensor element having a reference magnetization direction, wherein the at least one magnetic field sensor element is arranged such that a predetermined angle greater than about 0 degrees and less than about 90 degrees exists between the reference magnetization direction and a direction of a magnetic field to be sensed by the sensor such that a saturation point of the at least one magnetic field sensor element increases as a magnitude of the magnetic field to be sensed increases.

2. The sensor of claim 1, further comprising a plurality of magnetic field sensor elements arranged to form a differential sensor.

3. The sensor of claim 2, wherein each of the plurality of magnetic field sensor elements have the same reference magnetization direction.

4. The sensor of claim 1, wherein the at least one magnetic field sensor element comprises a magnetoresistive sensor element.

5. The sensor of claim 4, wherein the magnetoresistive sensor element comprises one of a giant magetoresistive sensor element (GMR) or a tunneling magnetoresistive sensor element (TMR).

6. The sensor of claim 1, wherein the predetermined angle is greater that about 5 degrees and less than about 50 degrees.

7. The sensor of claim 6, wherein the predetermined angle is greater than about 25 degrees and less than about 30 degrees.

8. The sensor of claim 7, wherein the predetermined angle is about 22.5 degrees.

9. The sensor of claim 1, further comprising a substrate, wherein the at least one magnetic field sensor element is mounted on the substrate.

10. The sensor of claim 1, wherein the predetermined angle is selected to extend a range of the at least one magnetic field sensor element between positive saturation and negative saturation.

11. The sensor of claim 1, wherein a shape anisotropy easy axis of the at least one sensor element has a direction different from the reference magnetization direction.

12. The sensor of claim 1, wherein the at least one magnetic field sensor element has a width and a length, the length being longer than the width, and wherein the at least one magnetic field sensor element is arranged such that an axis parallel with the length is at a non-zero angle with respect to the direction of a magnetic field to the sensed by the sensor.

13. The sensor of claim 1, wherein the direction of the magnetic field to be sensed by the sensor is one of a direction of movement of a target or pole wheel, or a direction of current flow.

14. A sensor comprising:
a bias magnetic field source configured to induce a bias magnetic field; and
at least one magnetic field sensor element, wherein the at least one magnetic field sensor element is arranged such that a predetermined angle greater than about 0 degrees and less than about 90 degrees exists between a direction of magnetization of the at least one magnetic field sensor element related to the bias magnetic field and a direction of a magnetic field to be sensed by the sensor such that a saturation point of the at least one magnetic field sensor element increases as a magnitude of the magnetic field to be sensed increases.

15. The sensor of claim 14, further comprising a plurality of magnetic field sensor elements arranged to form a differential sensor.

16. The sensor of claim 14, wherein the at least one magnetic field sensor element comprises a magnetoresistive sensor element.

17. The sensor of claim 16, wherein the magnetoresistive sensor element comprises an anisotropic magetoresistive sensor element.

18. The sensor of claim 14, wherein the predetermined angle is greater than about 5 degrees and less than about 50 degrees.

19. The sensor of claim 18, wherein the predetermined angle is greater than about 15 degrees and less than about 30 degrees.

20. The sensor of claim 19, wherein the predetermined angle is about 22.5 degrees.

21. The sensor of claim 14, further comprising a substrate, wherein the at least one magnetic field sensor element is mounted on the substrate.

22. The sensor of claim 14, wherein the predetermined angle is selected to extend a range of the at least one magnetic field sensor element between positive saturation and negative saturation.

23. The sensor of claim 14, wherein a shape anisotropy easy axis of the at least one sensor element has a direction different from the reference magnetization direction.

24. The sensor of claim 14, wherein the so tree comprises one of a bias magnet, a wire, or a plurality of wires.

25. The sensor of claim 14, wherein the direction of the magnetic field to be sensed by the sensor is one of a direction of movement of a target or pole wheel, or a direction of current flow.

26. A method of extending a non-saturation range magnetoresistive magnetic field sensor comprising:
determining a direction of a magnetic field to be sensed; and
arranging a magnetoresistive magnetic field sensor to form a predetermined non-zero angle between a magnetization direction of the magnetoresistive magnetic field sensor and the direction of the magnetic field to be sensed such that a saturation point of the at least one magnetoresistive magnetic field sensor increases as a magnitude of the magnetic field to be sensed increases.

27. The method of claim 6 wherein the magnetoresistive sensor comprises an anisotropic magnetoresistive (AMR) magnetic field sensor and the magnetization direction of the AMR magnetic field sensor is a direction of a bias magnetic field.

28. The method of claim 26, wherein the magnetoresistive sensor comprises a giant magnetoresistive (GMR) magnetic field sensor and the magnetization direction of the GMR magnetic field sensor is a reference magnetization direction.
